(19) United States
(12) Patent Application Publication
(10) Pub. No.: US 2025/0323100 A1
(43) Pub. Date: Oct. 16, 2025

(54) METHOD OF MANUFACTURING SEMICONDUCTOR DEVICE

(71) Applicant: Renesas Electronics Corporation, Tokyo (JP)

(72) Inventor: Hirofumi FUKUDA, Tokyo (JP)

(21) Appl. No.: 19/066,322

(22) Filed: Feb. 28, 2025

(30) Foreign Application Priority Data
Apr. 15, 2024 (JP) 2024-065752

(51) Int. Cl. H01L 21/78; H01L 21/304; H01L 21/683

(52) U.S. Cl. CPC H01L 21/78; H01L 21/304; H01L 21/6836

(57) ABSTRACT

After grinding a back surface of a semiconductor substrate SB such that a thickness of a central portion of the semiconductor substrate is less than a thickness of a peripheral portion of the semiconductor substrate, a metal film including a film made of silver or copper is formed on the back surface of the semiconductor substrate. Thereafter, a dicing tape is adhered to the back surface of the semiconductor substrate via the metal film. A base material layer of the dicing tape is made of polyvinyl chloride. Also, after separating the peripheral portion from the central portion and the dicing tape, the semiconductor substrate adhered to the dicing tape is diced. Thereafter, the semiconductor substrate adhered to the dicing tape is transported.

### CROSS-REFERENCE TO RELATED APPLICATIONS

The disclosure of Japanese Patent Application No. 2024-065752 filed on Apr. 15, 2024, including the specification, drawings and abstract is incorporated herein by reference in its entirety.

### BACKGROUND

The present invention relates to a method for manufacturing a semiconductor device, and can be suitably used, for example, in a method for manufacturing a semiconductor device having a process of dicing a semiconductor wafer equipped with a backside metal film.

After attaching a dicing tape to a back surface of a semiconductor wafer, the semiconductor wafer can be divided into a plurality of semiconductor chips by dicing the semiconductor wafer.

There are disclosed techniques listed below.
[Patent Document 1] Japanese Unexamined Patent Application Publication No. 2016-192450
[Patent Document 2] Japanese Unexamined Patent Application Publication No. 2011-222843

Patent Document 1 and Patent Document 2 discloses that a dicing tape is attached to a back surface of a semiconductor wafer after polishing the back surface of the semiconductor wafer such that a thickness in a central portion of the semiconductor wafer is less than a thickness in a peripheral portion of the semiconductor wafer.

### SUMMARY

In general, a gold (Au) film is used as the back surface electrode of a semiconductor chip. However, the present inventor is considering using, for example, a silver (Ag) film, that is a material which is more easily oxidized than the gold film, as the back surface electrode of the semiconductor chip. The cost of silver is lower than that of gold. Therefore, when the silver film is used as the back surface electrode of the semiconductor chip instead of the gold film, the manufacturing cost of the semiconductor chip can be reduced.

However, as mentioned above, silver is more easily oxidized compared to gold. And, when the silver film is oxidized, there is a possibility that the performance and reliability of a semiconductor device assembled by using the semiconductor chip may be decreased. Therefore, it is desirable to take some measures to prevent the oxidation of the back surface electrode made of a material that is more easily oxidized than the gold film.

Other objects and novel features will become apparent from the description of this specification and the accompanying drawings.

According to one embodiment, a method for manufacturing a semiconductor device, includes: a step of grinding a second main surface of a semiconductor wafer such that a thickness of a central portion of the semiconductor wafer is less than a thickness of a peripheral portion of the semiconductor wafer; a step of forming a metal film including a first metal film made of silver or copper on the second main surface of the semiconductor wafer; and a step of adhering a dicing tape to the second main surface of the semiconductor wafer via the metal film. The method further includes: a step of separating the peripheral portion from the central portion and the dicing tape; a step of dicing the semiconductor wafer adhered to the dicing tape; and a step of transporting the semiconductor wafer adhered to the dicing tape and diced. The dicing tape has a base material layer and an adhesive layer on the base material layer. The base material layer is made of polyvinyl chloride.

According to one embodiment, it is possible to prevent the oxidation of the backside electrode of the semiconductor chip.

### BRIEF DESCRIPTION OF THE DRAWINGS

FIG. 1 is a process flow diagram showing a manufacturing process of a semiconductor device according to one embodiment.

FIG. 2 is a plan view showing a semiconductor substrate used in the manufacturing process of the semiconductor device according to one embodiment.

FIG. 3 is a cross-sectional view along line A1-A1 of the semiconductor substrate of FIG. 2.

FIG. 4 is a cross-sectional view of the semiconductor substrate after a wiring structure forming step has been performed.

FIG. 5 is a plan view showing a back surface of a wafer after a back surface grinding step has been performed.

FIG. 6 is a cross-sectional view along line A1-A1 of FIG. 5.

FIG. 7 is a cross-sectional view near an edge of the semiconductor substrate after the back surface grinding step has been performed.

FIG. 8 is an explanatory diagram of the back surface grinding step.

FIG. 9 is a cross-sectional view of the wafer after a back surface metal film forming step has been performed.

FIG. 10 is a cross-sectional view near the edge of the semiconductor substrate after the back surface metal film forming step has been performed.

FIG. 11 is an enlarged partial cross-sectional view showing the back surface of the semiconductor substrate and a metal film formed on the back surface of the semiconductor substrate.

FIG. 12 is a plan view showing the wafer after a dicing tape adhering step has been performed.

FIG. 13 is a cross-sectional view along line A1-A1 of FIG. 12.

FIG. 14 is a cross-sectional view near the edge of the semiconductor substrate after the dicing tape adhering step has been performed.

FIG. 15 is an enlarged partial cross-sectional view showing the back surface of the semiconductor substrate, the metal film formed on the back surface of the semiconductor substrate, and the dicing tape formed on the metal film.

FIG. 16 is an explanatory diagram of the dicing tape adhering step.

FIG. 17 is an enlarged partial cross-sectional view of a portion of FIG. 16.

FIG. 18 is an explanatory diagram of the dicing tape adhering step.

FIG. 19 is an explanatory diagram of the peripheral portion separating step.

FIG. 20 is an enlarged partial cross-sectional view of the portion of FIG. 19.

FIG. 21 is an explanatory diagram of the peripheral portion separating step.

FIG. 22 is a plan view of the wafer after completing the peripheral portion separating step.

FIG. 23 is an explanatory diagram of the dicing step.

FIG. 24 is an explanatory diagram of the dicing step.

FIG. 25 is a plan view of a wafer after completing the dicing step.

FIG. 26 is a cross-sectional view along line A1-A1 of FIG. 25.

FIG. 27 is a cross-sectional view showing an example of a semiconductor device assembled by using a semiconductor chip obtained.

FIG. 28 is an explanatory diagram of a picking up step for obtaining the semiconductor chip from a structure.

### DETAILED DESCRIPTION

In the following embodiments, for convenience, when necessary, they are divided into multiple sections or embodiments for explanation. Except when specifically indicated, they are not unrelated to each other; rather, one is related to the other as a modification, detail, supplementary explanation, etc., of part or all of the other. Additionally, in the following embodiments, when referring to the number of elements (including the number of elements, numerical values, quantities, ranges, etc.), unless specifically indicated or clearly limited to a specific number in principle, the specific number is not limiting and may be more or less than the specific number. Furthermore, in the following embodiments, it goes without saying that the constituent elements (including element steps, etc.) are not necessarily essential, except in cases where they are specifically indicated or considered to be obviously essential in principle. Similarly, in the following embodiments, when referring to the shapes, positional relationships, etc., of components, unless specifically indicated or considered not to be so in principle, it is assumed to include those that are substantially approximate to or similar to the shapes, etc. The same applies to the above numerical values and ranges.

Hereinafter, embodiments will be described in detail based on the drawings. In all the drawings for explaining the embodiments, members having the same functions are denoted by the same reference numerals, and repetitive descriptions thereof are omitted. Also, in the following embodiments, descriptions of the same or similar parts will not be repeated in principle except when particularly necessary.

In the drawings used in the embodiments, hatching may be omitted even in the case of cross-sectional views in order to make the drawings easier to see. Also, hatching may be applied even in the case of plan views to make the drawings easier to see.

### Embodiment

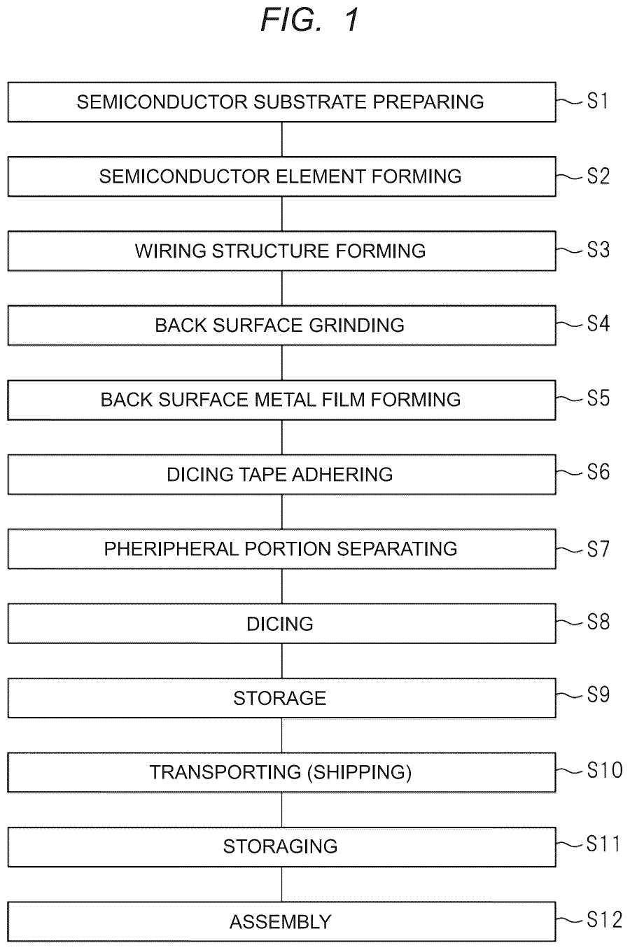

The method of manufacturing the semiconductor device of the present embodiment will be described. FIG. 1 is a process flow diagram showing the method of manufacturing the semiconductor device of the present embodiment.

### <Semiconductor Substrate Preparing Step>

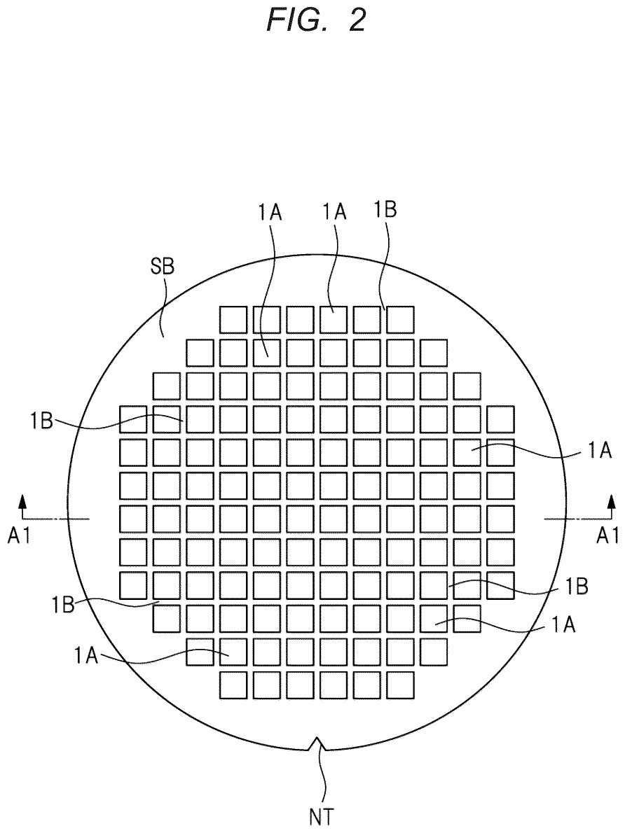

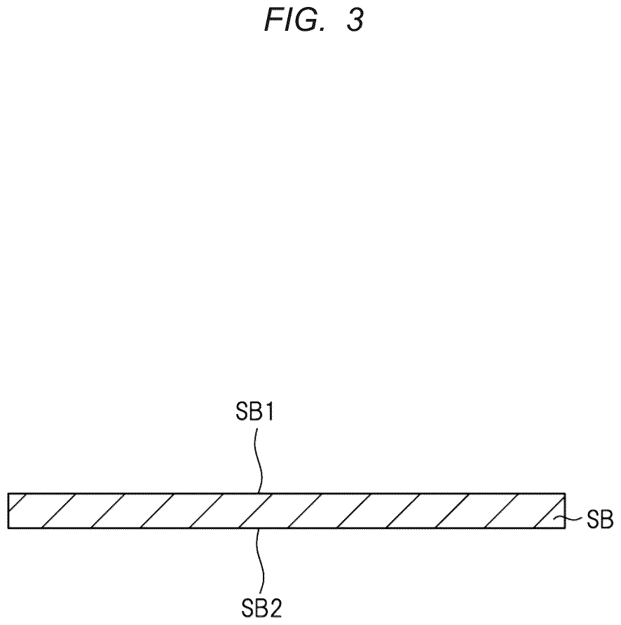

FIG. 2 is a plan view showing the semiconductor substrate SB used in the method of manufacturing the semiconductor device of the present embodiment. FIG. 3 is a cross-sectional view along line A1-A1 of the semiconductor substrate SB in FIG. 2.

As shown in FIGS. 2 and 3, a semiconductor substrate (semiconductor wafer) SB made of single-crystal silicon, etc., is prepared (step S1 in FIG. 1). The semiconductor substrate SB prepared in step S1 is a substantially disc-shaped semiconductor wafer. The semiconductor substrate SB may have a notch NT to identify the planar orientation of the semiconductor substrate SB.

As shown in FIG. 2, the semiconductor substrate SB has a plurality of chip regions 1A, which is an area where the semiconductor chip is to be obtained, and a scribe region 1B between the chip regions 1A adjacent to each other, and in plan view, each chip region 1A is surrounded by the scribe region 1B. That is, in the semiconductor substrate SB, a plurality of chip regions 1A is arranged in an array, and a region between the adjacent chip regions 1A corresponds to the scribe region 1B. In the dicing step described later, each chip region 1A are divided by cutting (dicing) the semiconductor substrate SB along the scribe region 1B, thereby the semiconductor chips are obtained. At the stage of preparing the semiconductor substrate SB in step S1, the chip region 1A and the scribe region 1B are a virtual area, and there is no boundary between the chip region 1A and the scribe region 1B.

As shown in FIG. 3, the semiconductor substrate SB has a front surface SB1, which is one of the main surfaces, and a back surface SB2, which is another main surface opposite the front surface SB1. The thickness of the semiconductor substrate SB prepared in step S1 is uniform. In the semiconductor substrate SB prepared in step S1, the entire front surface SB1 is flat, and the entire back surface SB2 is flat.

### <Semiconductor Element Forming Step>

Next, the semiconductor element is formed in each of the plurality of chip areas 1A of the semiconductor substrate SB (step S2 in FIG. 1). An Example of the semiconductor element includes MISFET (Metal Insulator Semiconductor Field Effect Transistor) or Bipolar transistors. For example, a trench gate typed MISFET, LDMOS FET (Lateral Diffused Metal Oxide Semiconductor Field Effect Transistor), or IGBT (Insulated Gate Bipolar Transistor) can be formed on the semiconductor substrate SB as the semiconductor element.

### <Wiring Structure Forming Step>

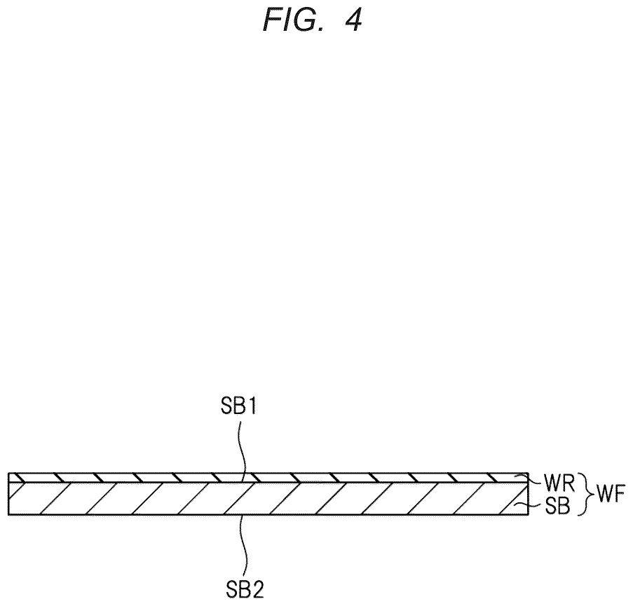

Next, as shown in FIG. 4, a wiring structure WR is formed on the front surface SB1 of the semiconductor substrate SB (step S3 in FIG. 1). FIG. 4 is a cross-sectional view of the semiconductor substrate SB after the wiring structure formation step of step S3, showing the cross-section corresponding to the above FIG. 3.

The wiring structure WR includes one or more layers of insulating layers, one or more layers of wiring layers, and an uppermost protective film (protective insulating film, passivation film). The uppermost wiring layer among the wiring layers included in the wiring structure WR contains a plurality of pads (pad electrodes). In the wiring structure WR, each pad is exposed from an opening portion of the protective film. In each chip area 1A, a predetermined circuit (integrated circuit) is formed by the semiconductor element formed in or on the surface of the semiconductor substrate SB and the wiring formed in the wiring structure WR.

Hereinafter, the entire one of the semiconductor substrate SB and the wiring structure WR on the front surface SB1 of the semiconductor substrate SB is referred to as a wafer (semiconductor wafer) WF. The back surface of the wafer WF corresponds to the back surface SB2 of the semiconductor substrate SB. The front surface of the wafer WF corresponds to the front surface of the wiring structure WR on the front surface SB1 of the semiconductor substrate SB. The front surface of the wafer WF and the back surface of the wafer WF are located on opposite sides to each other.

### <Back Surface Grinding Step>

Next, the back surface (back surface SB2 of the semiconductor substrate SB) of the wafer WF is ground (step S4 in FIG. 1). By performing the back surface grinding step of step S4, the thickness of the semiconductor substrate SB is reduced.

In the above step S2 and step S3, from the perspective of preventing damage to the semiconductor substrate SB, it is desirable to maintain a certain thickness of the semiconductor substrate SB. On the other hand, from the perspective of miniaturization of the semiconductor device, it is desirable to reduce the thickness of the semiconductor chip obtained after the dicing step described later. In the present embodiment, since the back surface grinding step of step S4 is performed after steps S2 and S3 to reduce the thickness of the semiconductor substrate SB, it is possible to prevent damage to the semiconductor substrate SB by maintaining its thickness in steps S2 and S3, and also to reduce the thickness of the semiconductor chip obtained after the dicing step described later.

However, unlike the present embodiment, if the entire back surface SB2 of the semiconductor substrate SB shown in FIG. 4 is uniformly ground in the back surface grinding step of step S4, and the entire thickness of the semiconductor substrate SB is uniformly thinned, the handleability of the wafer WF after the back surface grinding step of step S4 decreases. Also, in that case, there is a concern that a warping may occur in the wafer WF, and if the warping occurs, it can cause a decrease in processing accuracy in the dicing step.

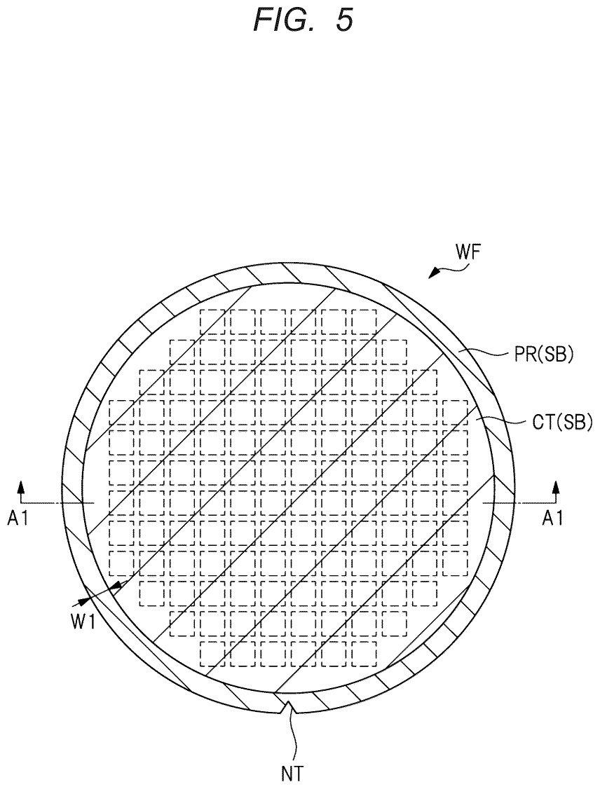

Therefore, in the present embodiment, as shown in FIGS. 5 to 7, in the back surface grinding step of step S4, the peripheral portion PR of the semiconductor substrate SB is hardly ground, while the central portion CT surrounded by the peripheral portion PR is selectively ground to be thinned.

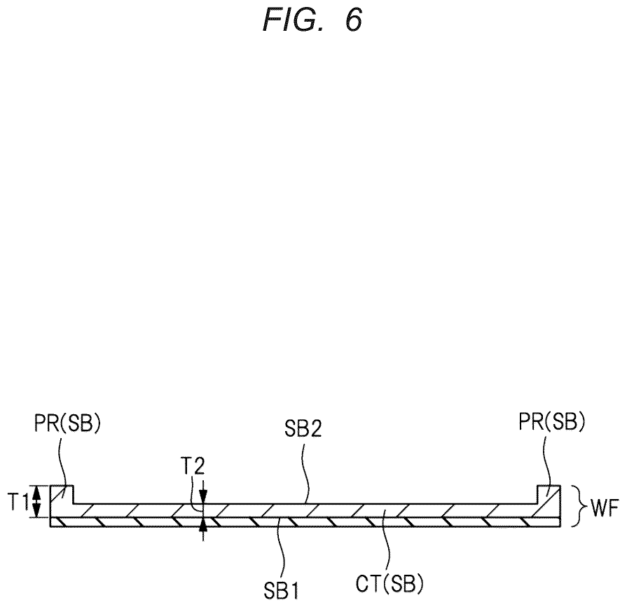

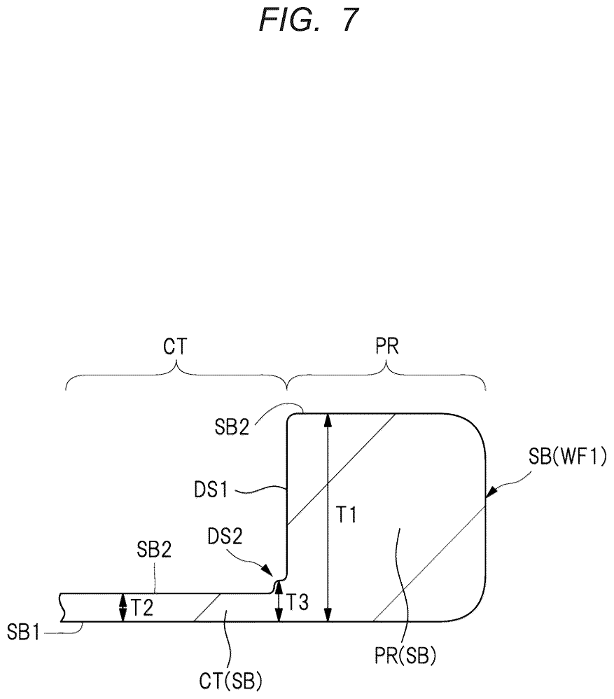

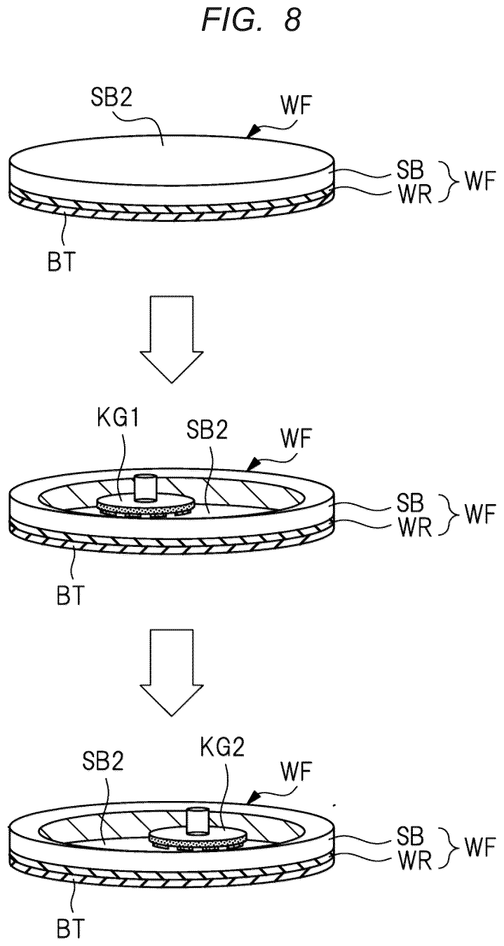

FIG. 5 is a plan view showing the back surface (back surface SB2 of semiconductor substrate SB) of the wafer after the back surface grinding step of step S4. FIG. 6 is a cross-sectional view along line A1-A1 in FIG. 5. In FIG. 6, wafer WF is illustrated with the back surface (back surface SB2 of semiconductor substrate SB) facing upwards. FIG. 5 is a plan view, but to facilitate understanding, different directions of hatching are applied to the central portion CT and the peripheral portion PR. Also, in FIG. 5, the plurality of chip regions 1A of the semiconductor substrate SB are indicated by a dotted line. FIG. 7 is a cross-sectional view near the edge of the semiconductor substrate SB after the back surface grinding step of step S4. In FIG. 7, the illustration of the wiring structure WR is omitted. FIG. 8 is an explanatory diagram of the back surface grinding step.

In plan view, the semiconductor substrate SB has the central portion CT and the peripheral portion PR that continuously surrounds the central portion CT (see FIG. 5). In the semiconductor substrate SB, the plurality of chip regions 1A is located within the central portion CT, and no chip regions 1A are placed within the peripheral portion PR.

Before the back surface grinding step of step S4, the entire back surface SB2 of the semiconductor substrate SB is flat, and the thickness of the semiconductor substrate SB is almost uniform. Therefore, before the back surface grinding step of step S4, the thickness of the central portion CT of the semiconductor substrate SB is the same as the thickness of the peripheral portion PR.

In the back surface grinding step of Step S4, as shown in FIGS. 6 and 7, the back surface SB2 of the semiconductor substrate SB is ground such that the thickness T2 of the central portion CT is less than the thickness T1 of the peripheral portion PR (T1>T2). The planar shape of the central portion CT is preferably circular. The planar shape of the peripheral portion PR is preferably annular.

Here, the thickness of the central portion CT of the semiconductor substrate SB at the completion of the back surface grinding step of Step S4 is referred to as thickness T2, and the thickness of the peripheral portion PR of the semiconductor substrate SB at the completion of the back surface grinding step of Step S4 is referred to as thickness T1. The thickness T2 of the central portion CT corresponds to the distance from the front surface SB1 to the back surface SB2 of the semiconductor substrate SB in the central portion CT. The thickness T1 of the peripheral portion PR corresponds to the distance from the front surface SB1 to the back surface SB2 of the semiconductor substrate SB in the peripheral portion PR. The thickness T2 of the central portion CT is less than the thickness T1 of the peripheral portion PR (T1>T2). The thickness T2 of the central portion CT is, for example, more than 50 micrometers and less than 150 micrometers, and the thickness T1 of the peripheral portion PR is, for example, more than 700 micrometers and less than 775 micrometers. The difference between the thickness T1 of the peripheral portion PR and the thickness T2 of the central portion CT of the semiconductor substrate SB is, for example, more than 550 micrometers and less than 725 micrometers.

Furthermore, as shown in FIG. 5, except for the portion where the notch NT is formed, the width W1 of the peripheral portion PR is substantially constant regardless of the location of the peripheral portion PR. The width W1 of the peripheral portion PR is, for example, at least 4000 micrometers and no more than approximately 6000 micrometers.

Thus, by increasing the thickness T1 of the peripheral portion PR surrounding the central portion CT, the peripheral portion PR can function as a reinforcing member that suppresses the warping of the semiconductor substrate SB. This improves the handleability of the wafer WF after the back surface grinding step in step S4 and can suppress or prevent the warping of the wafer WF. On the other hand, by reducing the thickness T2 of the central portion CT where the plurality of chip areas 1A is located, the thickness of the semiconductor chips obtained after the dicing step described later can be reduced.

Hereinafter, a specific example of the back surface grinding step of step S4 will be described with reference to FIG. 8.

First, as shown in the upper part of FIG. 8, a back grind tape BT is attached to the surface of the wafer WF. The back grind tape BT has a function to prevent contamination of semiconductor elements formed within or on the front surface SB1 of the semiconductor substrate SB or wiring layers of the wiring structure WR, etc., by grinding debris or cleaning water during the back surface grinding step. The back grind tape BT includes a resin film as a base material and an adhesive layer formed on one of main surfaces of the resin film. The back grind tape BT is attached to the front surface (front surface of wiring structure WR) of the wafer WF such that the adhesive layer of the back grind tape BT contacts the front surface of the wafer WF.

Next, although not shown in FIG. 8, with the back grind tape BT attached to the wafer WF, the entire back surface of the wafer WF is ground (preliminary grinding step). This reduces the overall thickness of the semiconductor substrate SB. This preliminary grinding step may be omitted.

Next, as shown in the middle part of FIG. 8, with the back grind tape BT attached to the wafer WF, the back surface (back surface SB2 of semiconductor substrate SB) of the wafer WF is ground by using a grinding tool KG1 such as a grindstone (rough grinding step). At this time, the central portion CT of the semiconductor substrate SB is selectively grounded until its thickness reaches a predetermined thickness.

Next, as shown in the lower part of FIG. 8, with the back grind tape BT attached to the wafer WF, the back surface (back surface SB2 of semiconductor substrate SB) of the wafer WF is ground by using a grinding tool KG2 such as a grindstone (finish grinding step). At this time, the central portion CT of the semiconductor substrate SB is selectively grounded until its thickness reaches the design target thickness. The grain size of the abrasive grains possessed by the grinding tool KG2 is smaller than the grain size of the abrasive grains possessed by the grinding tool KG1.

By performing grinding with the grinding tool KG1 having a large grain size in the rough grinding step, the total time required for the grinding step can be shortened. Then, by performing grinding with the grinding tool KG2 having a small grain size in the subsequent finishing grinding step, the flatness of the back surface SB2 in the central portion CT of the semiconductor substrate SB can be improved. Thus, it is possible to achieve both a reduction in the time required for the grinding step and an improvement in the flatness of the back surface SB2 in the central portion CT of the semiconductor substrate SB.

By selectively grinding the central portion CT of the semiconductor substrate SB in the back surface grinding step of Step S4, a step surface (step side, step portion) DS1 is formed at the boundary between the central portion CT and the peripheral portion PR of the semiconductor substrate SB, and the thickness T2 of the central portion CT becomes thinner than the thickness T1 of the peripheral portion PR of the semiconductor substrate SB.

As described above, when the rough grinding step and the subsequent finishing grinding step are performed in the back surface grinding step of Step S4, as shown in FIG. 7, a small step portion DS2, continuous with the step surface DS1, is also formed at the boundary between the central portion CT and the peripheral portion PR. The height difference between the step portion DS2 and the central portion CT is smaller than the height difference between the peripheral portion PR and the central portion CT, and also smaller than the thickness of the central portion CT. The height difference between the step portion DS2 and the central portion CT corresponds to the difference between the thickness T3 of the step portion DS2 and the thickness T2 of the central portion CT. The thickness T3 of the step portion DS2 is, for example, more than 100 micrometers and less than 250 micrometers. Moreover, the height difference of the step portion DS2 is, for example, more than 50 micrometers and about 100 micrometers.

The step surface DS1 and the step portion DS2 are located at the boundary (between) the central portion CT and the peripheral portion PR, the back surface of the peripheral portion PR continues to the step surface DS1, and the back surface of the central portion CT continues to the step portion DS2. The step portion DS2 is interposed between the step surface DS1 and the back surface of the central portion CT. That is, the step portion DS2 exists below the step surface DS1.

Thereafter, to remove the grinding debris and the grinding fluid adhered to the wafer WF, the wafer WF is subjected to a cleaning process. At this time, the back grind tape BT is peeled off from the wafer WF, and the surface of the wafer WF is also cleaned.

Thus, the back surface grinding step of step S4 is performed.

Unlike the present embodiment, if the entire semiconductor substrate SB is uniformly thinned, the warping of the wafer WF is likely to occur when the back grind tape BT is peeled off. However, in the present embodiment, as shown in FIGS. 5 to 7, around the central portion CT where the plurality of chip areas 1A is arranged, there exists the peripheral portion PR that is thicker than the central portion CT. Therefore, even if the back grind tape BT is peeled off from the wafer WF, it is possible to prevent the warping of the wafer WF.

Moreover, from the perspective of suppressing the warping of the wafer WF, it is desirable that the thickness T1 of the peripheral portion PR is large. On the other hand, increasing the width W1 of the peripheral portion PR can also suppress the warping of the wafer WF, but increasing the width W1 of the peripheral portion PR reduces the number of the semiconductor chips that can be obtained from one wafer WF. Therefore, to suppress the warping of the wafer WF, it is preferable to increase the thickness T1 of the peripheral portion PR rather than increasing the width W1 of the peripheral portion PR. Hence, from the perspective of increasing the number of the semiconductor chips that can be obtained from one wafer WF and improving manufacturing efficiency, the thickness T1 of the peripheral portion PR is preferably more than twice the thickness T2 of the central portion CT. Moreover, when the thickness T2 of the central portion CT is 100 micrometers or less, the thickness T1 of the peripheral portion PR is even more preferably more than five times the thickness T2 of the central portion CT.

### <Back Surface Metal Film Forming Step>

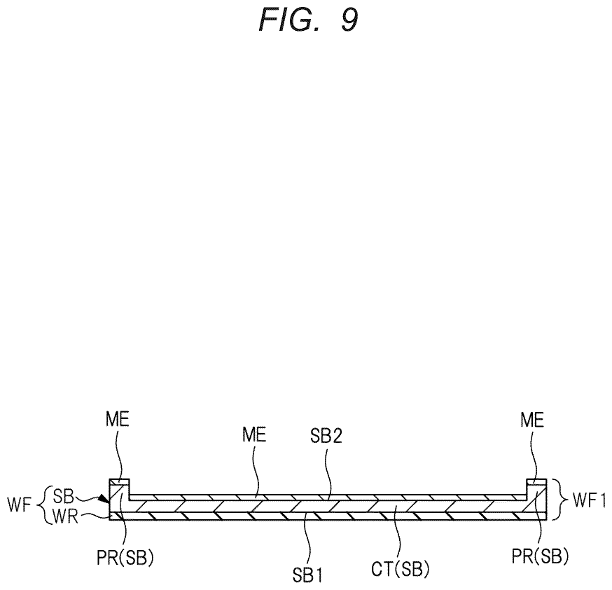

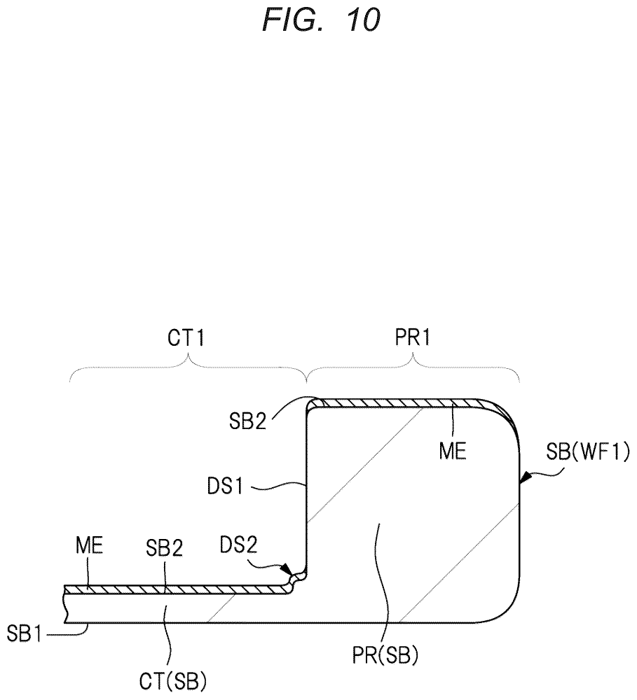

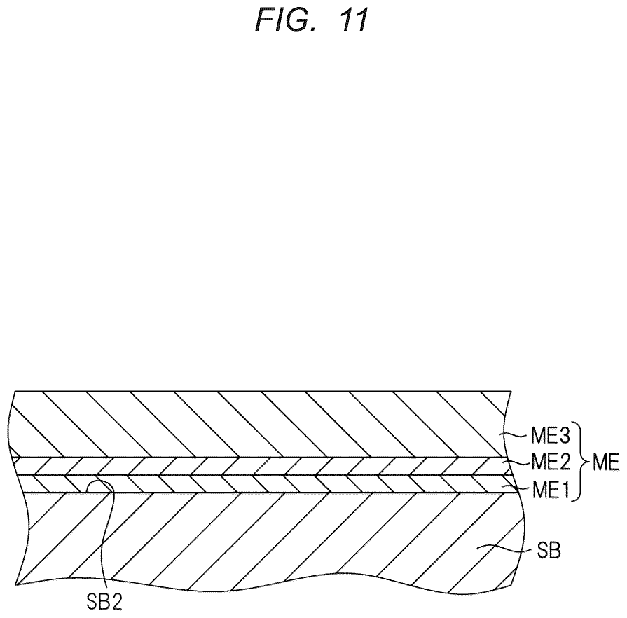

Next, as shown in FIGS. 9 to 11, a metal film ME is formed on the back surface (back surface SB2 of semiconductor substrate SB) of the wafer WF (step S5 in FIG. 1). FIG. 9 is a cross-sectional view of the wafer after the back surface metal film forming step of step S5 has been performed, showing the cross-section corresponding to the above FIG. 6. FIG. 10 is a cross-sectional view near the edge of the semiconductor substrate SB after the back surface metal film forming step of step S5 has been performed, showing the cross-section corresponding to the above FIG. 7. In FIG. 10, the illustration of the wiring structure WR is omitted. FIG. 11 is an enlarged partial cross-sectional view showing the back surface of the semiconductor substrate SB and the metal film ME formed on the back surface of the semiconductor substrate SB.

The metal film (back surface metal film, metal layer) ME is formed on almost the entire back surface (back surface SB2 of semiconductor substrate SB) of the wafer WF. Although the metal film ME may not be formed on the step surface DS1, in any case, the metal film ME is formed on the entire back surface of the central portion CT of the semiconductor substrate SB. The metal film ME is also formed on the back surface of the peripheral portion PR, but it is not essential for the metal film ME to be formed on the back surface of the peripheral portion PR.

By forming the metal film, ME on the back surface of the wafer WF in step S5, the semiconductor chip obtained after the dicing step described later has a back surface electrode made of the metal film ME.

The present inventors are considering using a silver (Ag) film (metal film made of silver) instead of a gold (Au) film (metal film made of gold) as the back surface electrode of the semiconductor chip. When the silver (Ag) film is used instead of the gold (Au) film as the back surface electrode of the semiconductor chip, the manufacturing cost of the semiconductor chip can be reduced.

The semiconductor chip obtained after the dicing step described later has the back surface electrode made of the metal film ME. Therefore, in the present embodiment, the metal film ME does not include the gold (Au) film but includes the silver (Ag) film.

Specifically, the metal film ME consists of a laminated film of multiple metal films, including the silver (Ag) film as the uppermost (top) layer. Note that, in the metal film ME, the layer in contact with the back surface SB2 of the semiconductor substrate SB is the lowermost (bottom) layer of the metal film ME, and the layer farthest from the back surface SB2 of the semiconductor substrate SB is the uppermost layer of the metal film ME, and the uppermost layer of the metal film ME made of silver (Ag) in the present embodiment. In other words, the silver (Ag) film ME3 included in the metal film ME is the front surface (exposed surface) of the metal film ME.

For example, as shown in FIG. 11, the metal film ME is comprised of a laminated film of a titanium (Ti) film ME1 formed on the back surface SB2 of the semiconductor substrate SB so as to contact with the back surface SB2, a nickel (Ni) film ME2 formed on the titanium film ME1, and a silver (Ag) film ME3 formed on the nickel film ME2. The titanium film MEL and the nickel film ME2 are interposed between the back surface SB2 of the semiconductor substrate SB and the silver (Ag) film ME3. The titanium film ME1 is interposed between the back surface SB2 of the semiconductor substrate SB and the nickel film ME2, and the nickel film ME2 is interposed between the titanium film ME1 and the silver (Ag) film ME3. The metal film ME can be formed, for example, by a sputtering method. When the metal film ME is formed by the sputtering method, the metal film ME is hardly formed on the step surface DS1 as shown in FIG. 10. In that case, the metal film ME on the back surface of the central portion CT and the metal film on the back surface of the peripheral portion PR are not connected to each other.

Moreover, in Step S5, after forming the metal film ME, it is also possible to perform a roughening treatment on the front surface (front surface of silver film ME3) of the metal film ME. This can increase the adhesion between the metal film ME and the dicing tape DT in the dicing tape attaching step of the Step S6 described later.

Hereinafter, the combination of the wafer WF and the metal film ME formed on the back surface of the wafer WF is referred to as a wafer (semiconductor wafer) WF1. That is, the combination of the semiconductor substrate SB, the wiring structure WR on the front surface SB1 of the semiconductor substrate SB, and the metal film ME on the back surface SB2 of the semiconductor substrate SB corresponds to the wafer WF1. The back surface of the wafer WF1 corresponds to the front surface of the metal film ME formed on the back surface SB2 of the semiconductor substrate SB. The front surface of the wafer WF1 corresponds to the front surface of the wiring structure WR on the front surface SB1 of the semiconductor substrate SB. The front surface of the wafer WF1 and the back surface of the wafer WF1 are located on opposite sides to each other. Note that the front surface of the metal film ME corresponds to the surface (main surface) opposite the surface in contact with the back surface SB2 of the semiconductor substrate SB.

Furthermore, hereinafter, the combination of the peripheral portion PR of the semiconductor substrate SB, the wiring structure WR on the front surface of the peripheral portion PR, and the metal film ME on the back surface of the peripheral portion PR is referred to as a peripheral portion PR1. The back surface of the peripheral portion PR1 corresponds to the front surface of the metal film ME on the back surface of the peripheral portion PR of the semiconductor substrate SB.

Further, in the following, the entirety of the central portion CT of the semiconductor substrate SB, the wiring structure WR on the central portion CT, and the metal film ME on the back surface of the central portion CT, shall be referred to as a central portion CT1. The back surface of the central portion CT1 corresponds to the front surface of the metal film ME on the back surface of the central portion CT of the semiconductor substrate SB. In plan view, the boundary between the central portion CT1 and the peripheral portion PR1 coincides with the boundary between the central portion CT and the peripheral portion PR.

### <Dicing Tape Adhering Step>

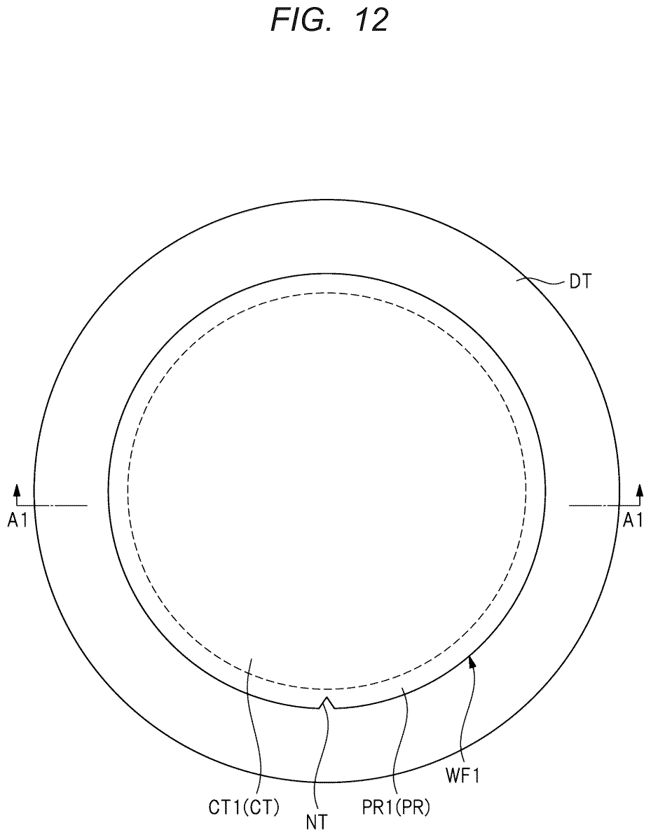

Next, as shown in FIGS. 12 to 15, a dicing tape (protective tape) DT is attached to the back surface of the wafer WF1 (step S6 of FIG. 1). In other words, in step S6, the dicing tape DT is attached to the back surface SB2 of the semiconductor substrate SB via the metal film ME.

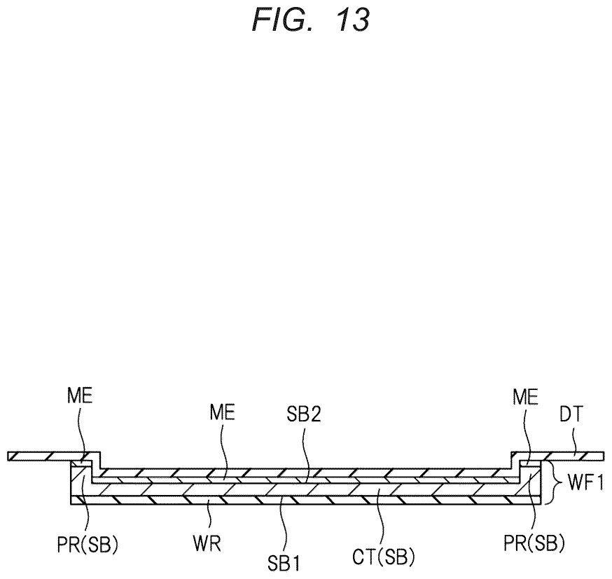

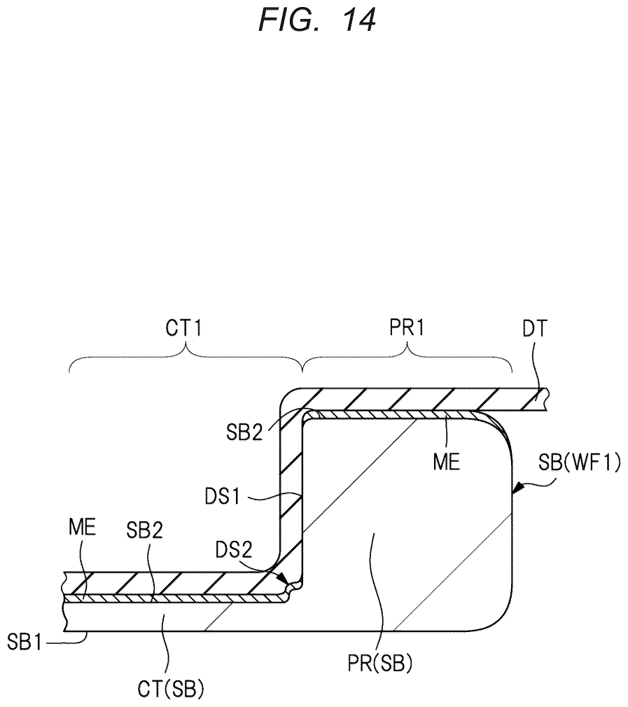

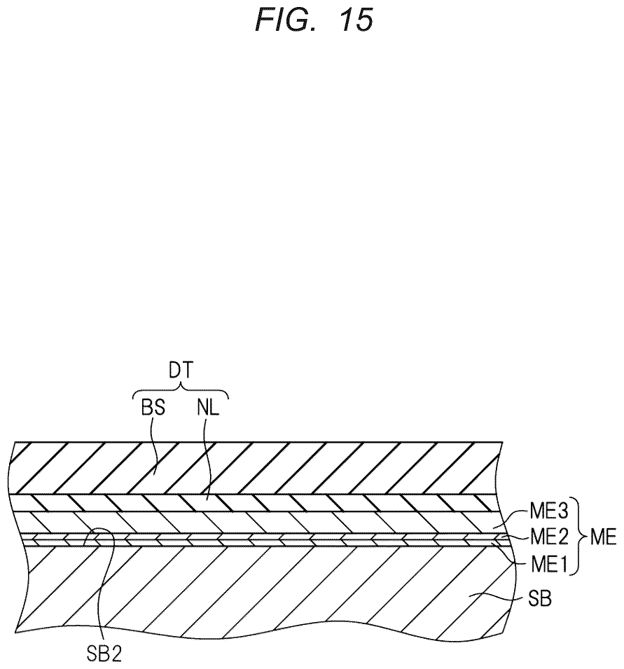

FIG. 12 is a plan view showing the wafer after the dicing tape adhering step of step S6. In FIG. 12, the position of the boundary between the central portion CT1 and the peripheral portion PR1 of the wafer WF1 is indicated by a dotted line. FIG. 13 is a cross-sectional view along the line A1-A1 of FIG. 12. In FIG. 13, the wafer WF1 is illustrated in an orientation where the back surface of the wafer WF1 faces upwards. FIG. 14 is a cross-sectional view near the edge of the semiconductor substrate SB after the dicing tape adhering step of step S6, showing the cross-section corresponding to the above FIG. 10. In FIG. 14, the illustration of the wiring structure WR is omitted. FIG. 15 is an enlarged partial cross-sectional view showing the back surface of the semiconductor substrate SB, the metal film ME formed on the back surface of the semiconductor substrate SB, and the dicing tape DT formed on the metal film ME.

As shown in FIG. 15, the dicing tape DT has a base material layer (substrate layer) BS, and an adhesive layer (bonding layer) NL formed on one of main surfaces of the base material layer BS. That is, the dicing tape DT has a laminated structure including the base material layer BS and the adhesive layer NL. In the present embodiment, the base material layer BS is made of polyvinyl chloride (PVC). The adhesive layer NL is made of acrylic resin. The thickness of the base material layer BS is preferably more than 70 micrometers and less than 100 micrometers. The thickness of the adhesive layer NL is preferably more than 5 micrometers and less than 10 micrometers. The dicing tape DT is attached to the back surface (front surface of metal film ME) of the wafer WF1 such that the adhesive layer NL of the dicing tape DT faces (contacts) the back surface (front surface of metal film ME) of the wafer WF1.

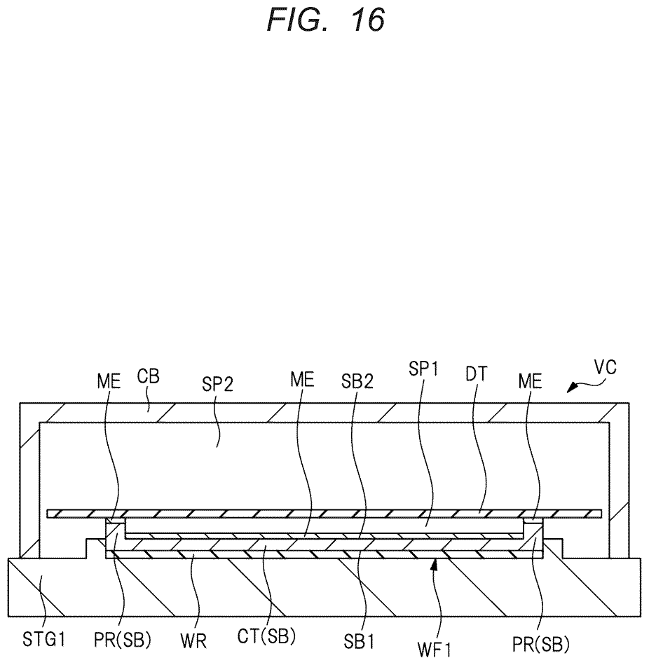

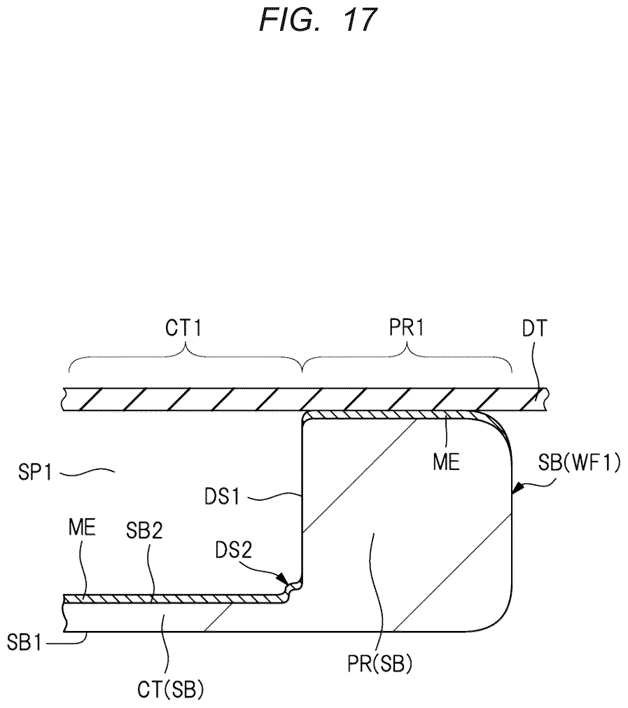

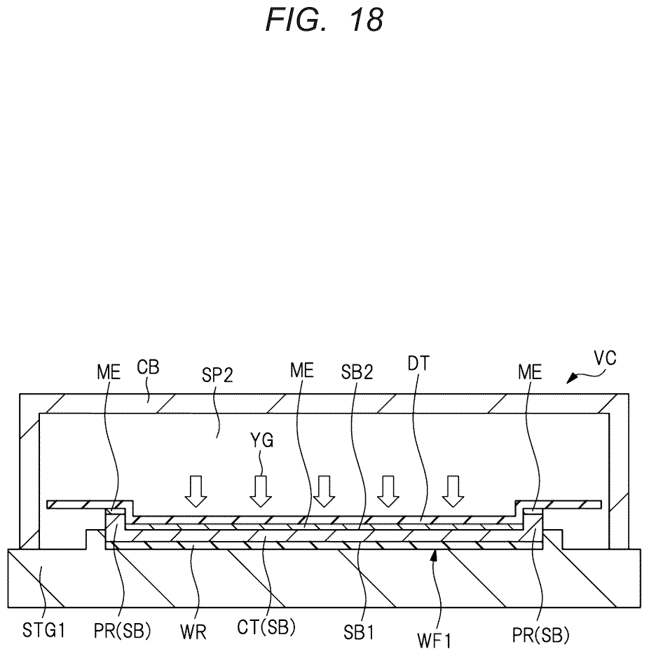

Hereinafter, a specific example of the dicing tape attaching step of step S6 will be described with reference to FIGS. 16 to 18. FIGS. 16 and 18 are explanatory diagrams of the dicing tape adhering step. FIG. 17 is a partially enlarged cross-sectional view enlarging a part of FIG. 16, showing a cross-section corresponding to the above FIG. 14. In FIG. 17, the illustration of the wiring structure WR and the stage STG1 is omitted.

First, the wafer WF1 is placed in a vacuum container (vacuum chamber, vacuum room) VC (i.e., “wafer WF1 placement step”). The vacuum container VC has a stage STG1, and a container portion CB placed on the stage STG1. The wafer WF1 is placed on the stage STG1 such that the front surface (front surface of wiring structure WR) of the wafer WF1 faces the upper surface of the stage STG1. The back surface of the wafer WF1 placed on the stage STG1 faces upwards. The wafer WF1 placed on stage STG1 is covered with the container portion CB, but the wafer WF1 is separated from the inner surface of the container portion CB. The wafer WF1 is placed in the space enclosed by stage STG1 and the container portion CB.

Next, in a state that the wafer WF1 is placed in the vacuum container VC, the inside of the vacuum container VC is depressurized (i.e., “depressurizing step”). This depressurization step can be performed by evacuating the inside of the vacuum container VC using a vacuum pump (not shown). As a result, the inside of the vacuum container VC becomes a depressurized state (i.e., “vacuum state”).

Next, as shown in FIG. 16, the dicing tape DT is placed on the back surface of the wafer WF1 placed on the stage STG1 (i.e., “dicing tape DT placement step”). At this time, the dicing tape DT is placed on the back surface of the wafer WF1 such that the adhesive layer NL (refer to FIG. 15) of the dicing tape DT faces the back surface (front surface of metal film ME) of the wafer WF1. To facilitate handleability of the dicing tape DT, the outer periphery of the dicing tape DT can be held by a ring-shaped support member (not shown), and the dicing tape DT held by the support member can be placed on the back surface of the wafer WF1.

As shown in FIGS. 16 and 17, at the stage where the dicing tape DT is placed on the back surface of the wafer WF1, in the peripheral portion PR1, the dicing tape DT is in contact with the back surface of the wafer WF1, but in the central portion CT1, the dicing tape DT is not in contact with the back surface of the wafer WF1, and the back surface of the wafer WF1 is separated from the dicing tape DT. That is, the dicing tape DT is in contact with the back surface (front surface of metal film ME on back surface of peripheral portion PR) of the peripheral portion PR1, but is not in contact with the back surface (front surface of metal film ME on back surface of central portion CT) of the central portion CT1, and is separated from the back surface of the central portion CT1. Therefore, the step surface DS1 and the step portion DS2 are not in contact with the dicing tape DT. Between the back surface of the wafer WF1 and the dicing tape DT, there exists a space SP1 enclosed by the back surface (front surface of metal film ME on back surface of central portion CT) of the central portion CT1, the step surface DS1, the front surface of the metal film ME on the step portion DS2, and the dicing tape DT.

The dicing tape DT placement step is performed in a vacuum container VC under reduced pressure (i.e., “vacuum state”), so the space SP1 is also in a reduced pressure state (i.e., “vacuum state”). At this stage, the pressure inside space SP1 is the same as the pressure around the wafer WF1 (space SP2) where the dicing tape DT is placed.

Next, the inside of the vacuum container VC is opened to the atmosphere (i.e., “atmosphere release step”). FIG. 18 shows the state after performing the atmosphere release step. This atmosphere release step can be performed by stopping the exhaust from the vacuum container VC by an exhaust vacuum pump (not shown) and opening a valve (not shown) connected to the opening portion of the vacuum container VC to introduce atmosphere from outside the vacuum container VC into the vacuum container VC. As a result, since the inside of the vacuum container VC becomes atmospheric pressure, the surroundings of the wafer WF1 (space SP2) where the dicing tape DT is placed quickly become atmospheric pressure, but the space SP1 is less likely to transition to atmospheric pressure and is more likely to maintain a reduced pressure state. This is because the back surface (front surface of metal film ME on back surface of peripheral portion PR) of the peripheral portion PR1 is in contact with the dicing tape DT, making the space SP1 a nearly closed space, and when atmosphere flows into the vacuum container VC, it is difficult for the atmosphere to flow into the space SP1.

When the atmospheric release step is performed, the pressure difference between the inside of the vacuum container VC (i.e., “atmospheric pressure condition”) and the space SP1 (i.e., “reduced pressure condition”) causes the dicing tape DT to deform, compressing (reducing) the space SP1. That is, when the atmospheric release step is performed, the pressure around the wafer WF1 where the dicing tape DT is placed (space SP2) becomes larger than the pressure inside space SP1, and due to the difference between the pressure in space SP2 and the pressure in space SP1, a force in the direction of the arrow YG shown in FIG. 18 (a force pressing the dicing tape DT towards the wafer WF1) is applied to the dicing tape DT. As a result, as shown in FIG. 18, the dicing tape DT deforms to follow the shape of the back surface of the wafer WF1, making the dicing tape DT adhere to the entire back surface of the wafer WF1. Specifically, the dicing tape DT adheres to the back surface (front surface of metal film ME on back surface of peripheral portion PR) of the peripheral portion PR1, the step surface DS1, the metal film ME on the step portion DS2, and the back surface (front surface of metal film ME on back surface of central portion CT) of the central portion CT1 (refer to FIG. 14 and FIG. 18). In other words, the dicing tape DT adheres to the surface of the metal film ME on the back surface of the peripheral portion PR, the front surface of the metal film ME on the back surface of the central portion CT, the step surface DS1, and the front surface of the metal film ME on the step portion DS2 (refer to FIGS. 14 and 18). As a result, the dicing tape DT is affixed to the entire back surface of the wafer WF1 such that no gap is formed between the back surface of the wafer WF1 and the dicing tape DT.

Subsequently, the wafer WF1 to which the dicing tape DT is attached is removed from the vacuum container VC.

### <Pheripheral Portion Separating Step>

Next, the central portion CT1 and the peripheral portion PR1 are separated from each other by cutting the wafer WF1 along the boundary between the central portion CT (CT1) and the peripheral portion PR (PR1) (step S7 in FIG. 1).

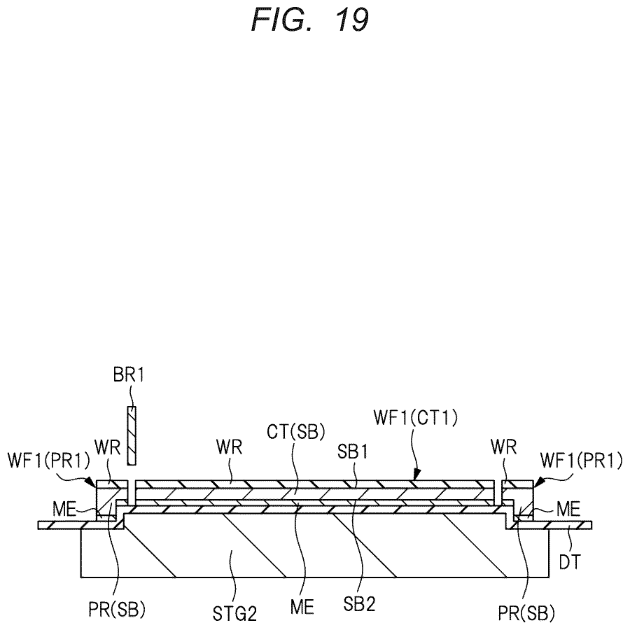

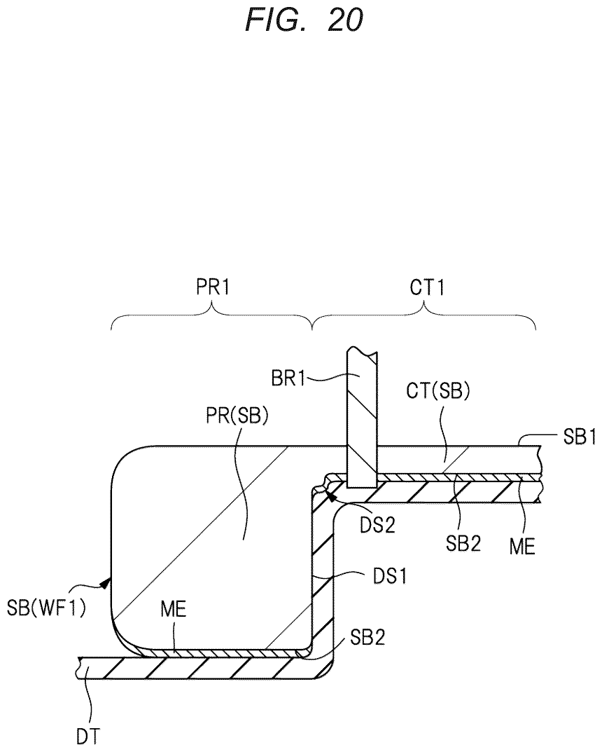

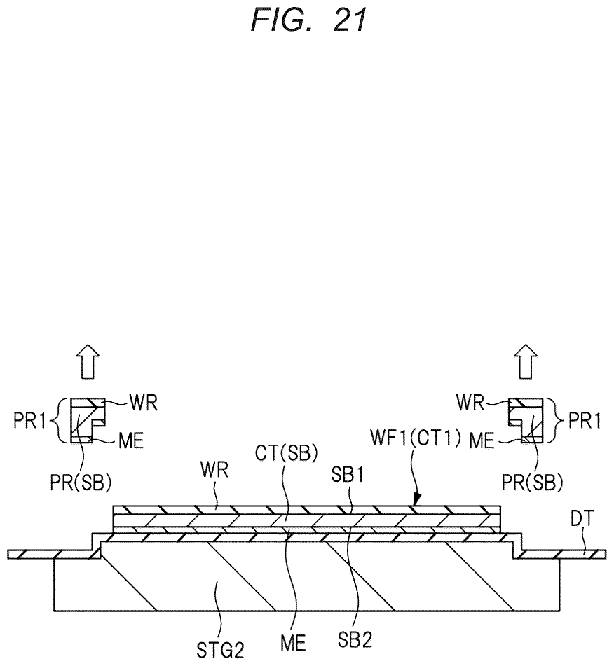

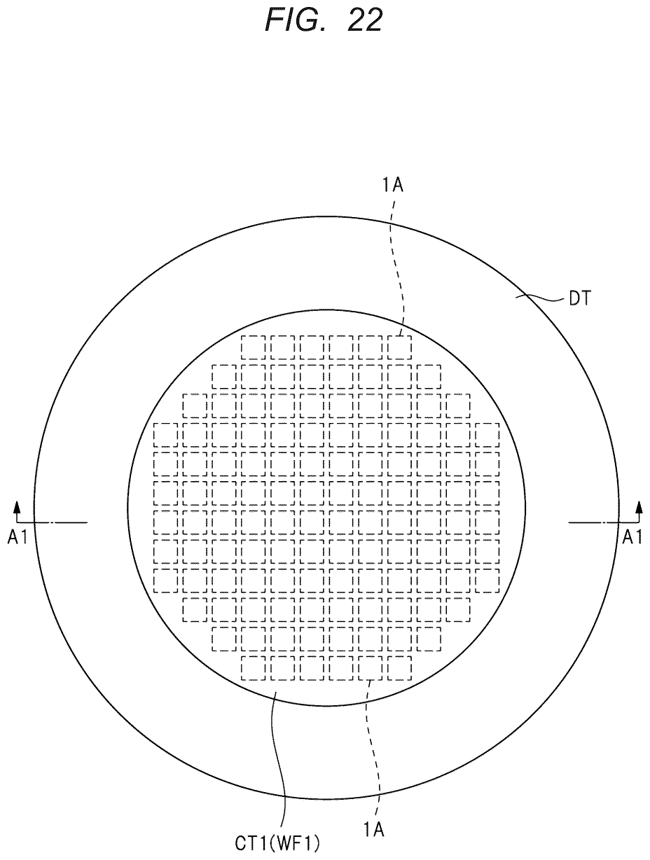

Hereinafter, a specific example of the peripheral portion separating step of step S7 will be described with reference to FIGS. 19 to 22. FIGS. 19 and 21 are explanatory diagrams of the peripheral separation process. FIG. 20 is a partially enlarged cross-sectional view of a part of FIG. 19, showing a cross-section corresponding to the above FIG. 14. In FIG. 20, the illustration of the wiring structure WR and the stage STG2 is omitted. FIG. 22 is a plan view of the wafer WF1 at the stage of completing the peripheral separation process of step S7. In FIG. 22, multiple chip areas 1A in the wafer WF1 are indicated by dotted lines.

First, as shown in FIG. 19, the wafer WF1 to which the dicing tape DT is attached is placed on the stage STG2 of the cutting apparatus. At this time, the wafer WF1 is placed on the stage STG2 in such a manner that the front surface of the wafer WF1 faces upward, and the dicing tape DT contacts the upper surface of the stage STG2. The upper surface of the stage STG2 has a shape that aligns with the back surface of the wafer WF1 and has a step at a position corresponding to the step surface DS1.

Next, as shown in FIGS. 19 and 20, the wafer WF1 is cut from the surface side along the boundary between the central portion CT (CT1) and the peripheral portion PR (PR1) using the blade (cutting edge) BR1 of the cutting apparatus (i.e., “cutting step”). In this cutting step, the wafer WF1 is cut such that the cutting line traces a circular orbit. Also, in this cutting step, it is preferable to cut the wafer WF1 slightly inside the boundary between the central portion CT (CT1) and the peripheral portion PR (PR1). In plan view, the side closer to the center of the central portion CT (CT1) corresponds to the inside, and the side farther from the center of the central portion CT (CT1) corresponds to the outside.

The wafer WF1 is cut by the rotating blade BR1, separating the central portion CT1 and the peripheral portion PR1, but the dicing tape DT is not completely cut. Therefore, the dicing tape DT located under the central portion CT1 and the dicing tape DT located under the peripheral portion PR1 remain integrally connected without being separated even after the cutting step.

Next, as shown in FIG. 21, the peripheral portion PR1 is separated from the dicing tape DT. For example, the peripheral portion PR1 can be separated from the dicing tape DT by peeling off the peripheral portion PR1 from the dicing tape DT using a pickup tool (not shown).

Since the peripheral portion PR1 was separated from the central portion CT1 in the cutting step described above, the peripheral portion PR1 can be separated from the dicing tape DT while the central portion CT remains attached to the dicing tape DT. This allows the peripheral portion PR1 to be selectively separated from the dicing tape DT.

In the cutting step, by cutting the wafer WF1 slightly inside the boundary between the central portion CT1 and the peripheral portion PR1, a part of the central portion (outer periphery) can also be separated from the dicing tape DT along with the peripheral portion PR1.

Thus, in step S7, the peripheral portion PR1 can be separated from the central portion CT1 and the dicing tape DT. Upon completion of the peripheral portion separating step of step S7, as shown in FIG. 22, the central portion CT1 of the wafer WF1 is adhered to the dicing tape DT, but the peripheral portion PR1 is not present on the dicing tape DT. Therefore, before the peripheral portion separating step of step S7, the wafer WF1 integrally has the peripheral portion PR1 and the central portion CT1, but after the completion of the peripheral portion separating step of step S7, the wafer WF1 is composed only of the central portion CT1, without having the peripheral portion PR1. The central portion CT1 has the plurality of chip regions 1A.

### <Dicing Step>

Next, the wafer WF1 (central portion CT1) adhered to the dicing tape DT is diced (cut) (step S8 in FIG. 1).

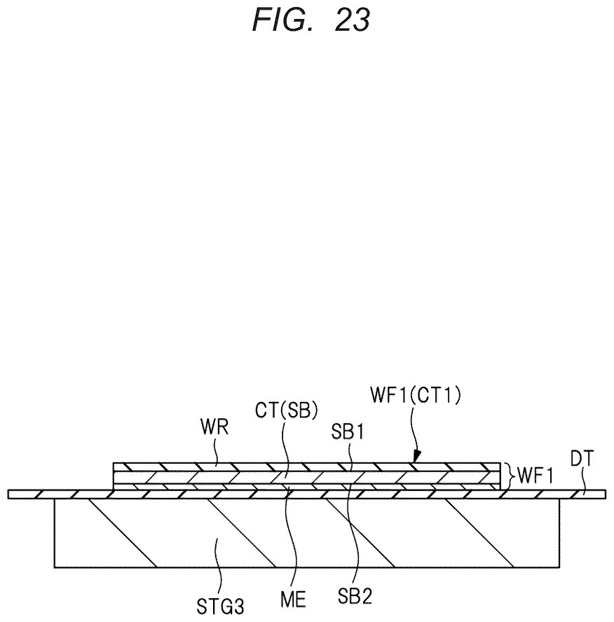

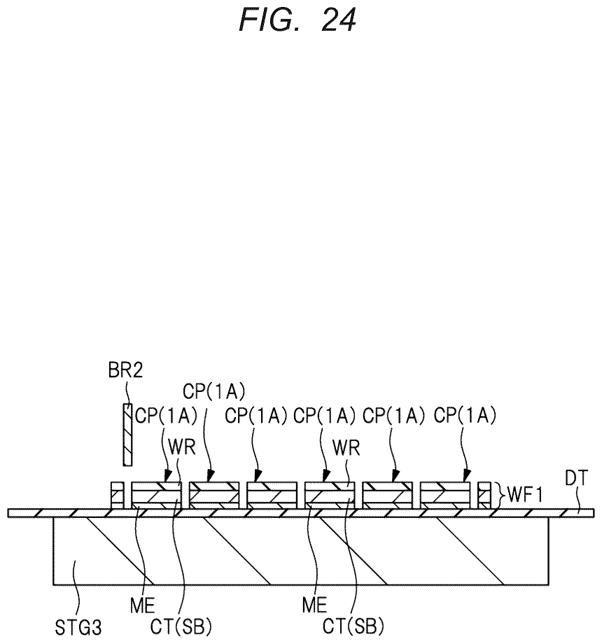

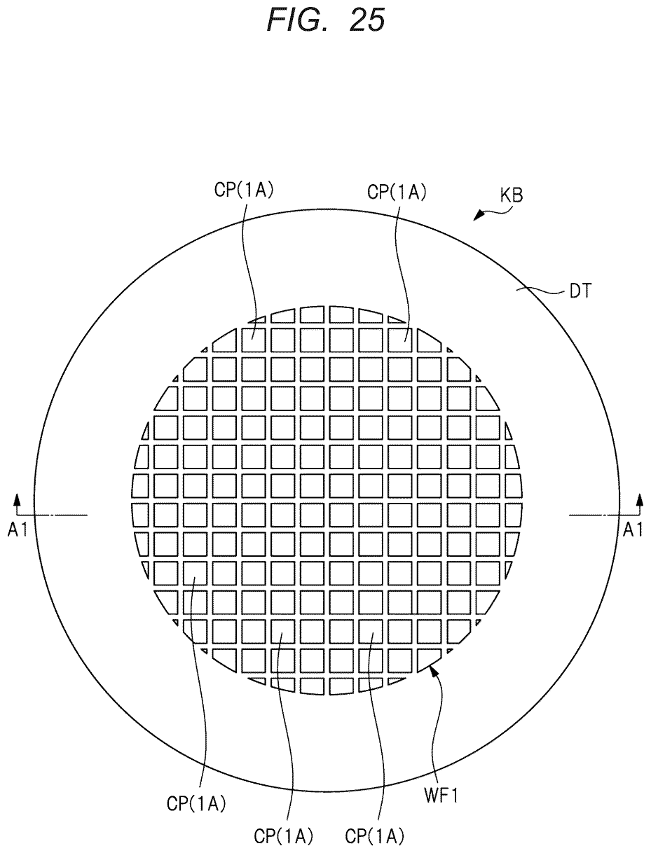

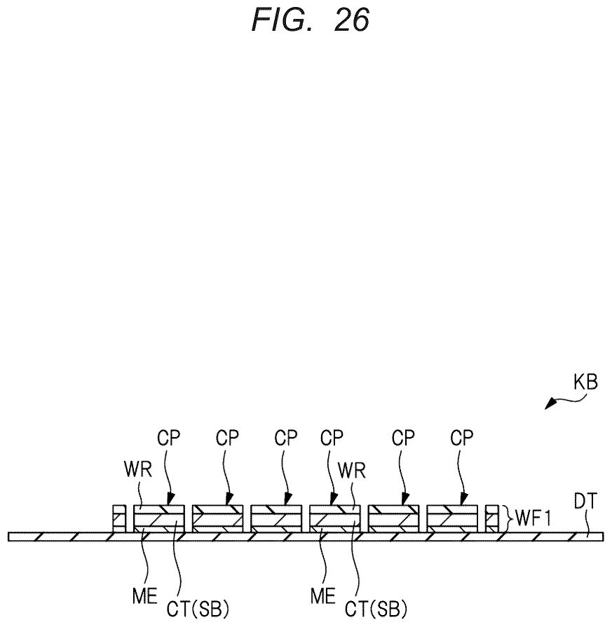

Hereinafter, a specific example of the dicing step in step S8 will be described with reference to FIGS. 23 to 25. FIGS. 23 and 24 are explanatory diagrams of the dicing process in step S8. FIG. 25 is a plan view of the wafer WF1 at the stage of completion of the dicing process in step S8. FIG. 26 is a cross-sectional view along the line A1-A1 of FIG. 25.

First, as shown in FIG. 23, the wafer WF1 to which the dicing tape DT is adhered is placed on the stage STG3 of the dicing device. At this time, the wafer WF1 is placed on the stage STG3 in such a manner that the front surface of the wafer WF1 faces upward, and the dicing tape DT faces (contacts) the upper surface of the stage STG3.

Next, as shown in FIGS. 24 and 25, the wafer WF1 is cut from the front surface side by the rotating blade (cutting edge) BR2 of the dicing device, along the scribe region 1B (refer to FIG. 2 above). As a result, the wafer WF1 is separated into a plurality of semiconductor chips CP and is divided (individualized). Each individualized chip region 1A corresponds to a semiconductor chip CP.

Each semiconductor chip CP is composed of chip region 1A of the semiconductor substrate SB, the wiring structure WR on the chip region 1A, and the metal film ME on the back surface of the chip region 1A. The cut surface of the wafer WF1 in the dicing step corresponds to the side surface of each semiconductor chip CP. The metal film ME of each semiconductor chip CP functions as the back surface electrode of that semiconductor chip CP.

Although the wafer WF1 is cut into multiple semiconductor chips CP by the rotating blade BR2, the dicing tape DT is not completely cut. Therefore, the dicing tape DT located under each semiconductor chip CP remain integrally connected without being separated, even after the dicing step.

Therefore, before the dicing step S8, a single wafer WF1 (central portion CT1) is in a state of being adhered to a single dicing tape DT, but upon completion of the dicing step S8, the diced wafer WF1 is in a state of being adhered to a single dicing tape DT, that is, a state where multiple semiconductor chips CP are adhered to a single dicing tape DT. The diced wafer WF1 is a collection of the plurality of semiconductor chips CP.

Hereinafter, the entirety of the dicing tape DT and the plurality of semiconductor chips CP (diced wafer WF1) adhered to the dicing tape DT will be referred to as the structure KB.

### <Storage Step>

Next, the structure KB shown in FIGS. 25 and 26 is stored until the transport step of step S10 described later is performed (step S9 in FIG. 1).

### <Transporting (Shipping) Step>

Next, the structure KB is transported (shipped) to customers, etc. (step S10 in FIG. 1). When the structure KB is transported to customers in step S10, the assembly process of the subsequent step S12 is performed at the customer's factory, etc. If the assembly process of the subsequent step S12 is performed at another factory of our company, in step S10, the structure KB is transported to another factory of our company.

### <Storage Step>

The structure KB transported in the transporting step of step S10 is stored until the assembly process of the subsequent step S12 is performed (step S11 in FIG. 1).

### <Assembly Process Of Semiconductor Device>

A semiconductor device (semiconductor package) is assembled by using the semiconductor chip CP obtained from the structure KB (step S12 in FIG. 1).

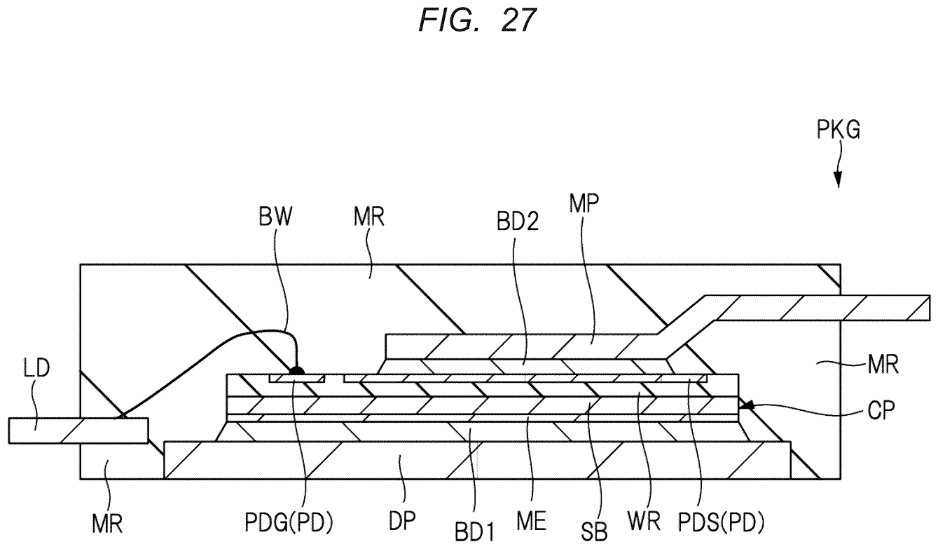

FIG. 27 is a cross-sectional view showing an example of a semiconductor device (semiconductor package) PKG assembled using the semiconductor chips CP obtained from the structure KB.

The semiconductor device PKG shown in FIG. 27 includes a die pad (chip mounting portion) DP, a semiconductor chip CP mounted on the die pad DP via a conductive bonding material BD1 such as solder, leads LD, bonding wires BW, a metal plate MP, and a sealing portion MR that seals these components.

The semiconductor chip CP consists of a semiconductor substrate SB, a wiring structure WR formed on the surface of the semiconductor substrate SB, and a metal film ME formed on the bottom surface of the semiconductor substrate SB. The back surface of the semiconductor chip CP is constituted by the surface of the metal film ME, which functions as a back surface electrode for the semiconductor chip CP. The wiring structure WR of the semiconductor chip CP has multiple pads (bonding pads) PD. In the case of FIG. 27, trench gate type MISFETs or LDMOSFETS are formed in the main surface of the semiconductor substrate SB of the semiconductor chip CP or within the semiconductor substrate SB, and the multiple pads PD of the semiconductor chip CP include a gate pad PDG and a source pad PDS. The gate pad PDG is electrically connected to the gate electrode of the trench gate type MISFET or LDMOSFET via the wiring in the wiring structure WR. The source pad PDS is electrically connected to the source region of the trench gate type MISFET or LDMOSFET via the wiring in the wiring structure WR. The metal film ME is electrically connected to the drain region of the trench gate type MISFET or LDMOSFET and can function as a back surface electrode for the drain.

The semiconductor chip CP is mounted on the die pad DP in an orientation facing the metal film ME, through a conductive bonding material BD1 such as solder. Therefore, the metal film ME of the semiconductor chip CP is electrically connected to the die pad DP through the conductive bonding material BD1.

The gate pad PDG of the semiconductor chip CP is electrically connected to the lead LD through a bonding wire BW. The die pad DP and the lead LD are made of a metal material, for example, copper (Cu) or a copper alloy. A part of the lead LD can be exposed from the sealing portion MR and function as an external terminal (external terminal for the gate). The backside of the die pad DP can be exposed from the backside of the sealing portion MR and function as an external terminal (external terminal for the drain).

One end of the metal plate MP is electrically connected to the source pad PDS of the semiconductor chip CP through a conductive bonding material BD2 such as solder. The other end of the metal plate MP protrudes from the sealing portion MR, and this protruding portion can function as an external terminal for the source. The other end of the metal plate MP can also be electrically connected to a lead for the source through a conductive bonding material, in which case, the lead for the source functions as an external terminal for the source. The sealing portion MR is made of a resin material and may contain fillers.

Next, an example of the assembly process (step S12 in FIG. 1) of the semiconductor device PKG shown in FIG. 27 will be described.

To manufacture the semiconductor device PKG, prepare a lead frame equipped with a die pad DP and leads LD.

Next, obtain the semiconductor chip CP from the structure KB and place the obtained semiconductor chip CP on the die pad DP of the lead frame through the conductive bonding material BD1. In this case, the semiconductor chip CP is placed on the die pad DP through the conductive bonding material BD1 in an orientation where the metal film ME of the semiconductor chip CP faces the die pad DP. Then, harden the bonding material BD1. In this way, the die bonding step is performed.

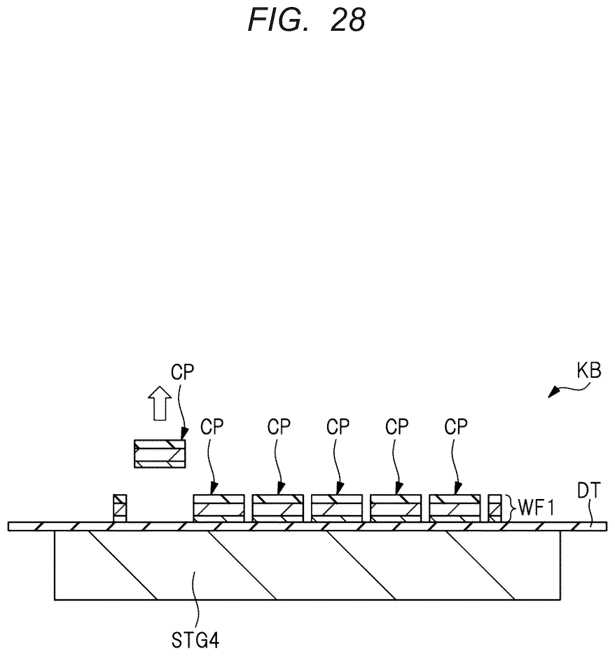

FIG. 28 is an explanatory diagram of the picking up step for obtaining the semiconductor chip CP from the structure KB. As described above, in the structure KB, the plurality of semiconductor chips CP is attached to a single dicing tape DT. For example, after irradiating the adhesive layer NL of the dicing tape DT of the structure KB with ultraviolet light, the structure KB is placed on the stage STG4 as shown in FIG. 28. Then, as shown in FIG. 28, the semiconductor chip CP is peeled off and picked up from the dicing tape DT by using a pickup tool such as a collet (not shown). The picked-up semiconductor chip CP is placed on the die pad DP of the lead frame via the conductive bonding material BD1, as described above.

After the die bonding step, a metal plate connecting step and a wire bonding step are performed. In the metal plate connecting step, one end of the metal plate MP is electrically connected to the source pad PDS of the semiconductor chip CP via a conductive bonding material BD2, such as solder. In the wire bonding step, the gate pad PDG of the semiconductor chip CP and the lead LD are electrically connected via a bonding wire BW. The metal plate connecting step and the wire bonding step can be performed in any order.

After the metal plate connecting step and the wire bonding step, a sealing portion forming step is performed to form an sealing portion MR.

After the sealing portion forming step, a lead frame cutting step is performed to separate the lead LD and the die pad DP from the frame of the lead frame. Subsequently, if necessary, steps such as bending the lead LD and plating the exposed portions of the lead LD and die pad DP are performed. In this way, a semiconductor device PKG can be assembled.

### <Background Of Study>

As described above, the inventors of the present application have been considering using a silver (Ag) film instead of a gold (Au) film as the backside electrode of the semiconductor chip. Therefore, when forming a backside metal film on the back surface of the semiconductor substrate, the formation of a metal film including a silver (Ag) film is being considered. Using a silver (Ag) film instead of a gold (Au) film can reduce the manufacturing cost of the semiconductor chip. However, a silver (Ag) film is more prone to oxidation compared to a gold (Au) film. If the silver film constituting the backside electrode is oxidized, there is a risk that the performance and reliability of the semiconductor device assembled using the semiconductor chip with the oxidized backside electrode may decrease. For this reason, the following two measures have been taken.

As a first measure, after dicing the semiconductor wafer with the metal film formed on the backside to obtain multiple semiconductor chips, the obtained semiconductor chips are stored in a chip tray or carrier tape, and the chip tray or carrier tape containing the multiple semiconductor chips is vacuum-packed in an aluminum bag for transportation (shipment). Vacuum packing in an aluminum bag can prevent the oxidation of the silver film contained in the backside metal film.

As a second measure, the semiconductor wafer with the metal film formed on the backside is stored in a wafer cassette without dicing, and the wafer cassette containing the semiconductor wafer is vacuum-packed in an aluminum bag for transportation (shipment). Vacuum packing in an aluminum bag can prevent the oxidation of the silver film contained in the backside metal film.

However, when implementing the first measure, it is necessary to perform the task of obtaining multiple semiconductor chips from the diced semiconductor wafer and storing the obtained semiconductor chips in a chip tray or carrier tape. This task can be labor-intensive and may increase costs.

Furthermore, when implementing the first measure, it is necessary to prepare a dedicated device (for example, a die bonding device compatible with chip trays or carrier tapes) in advance at the destination (shipment destination) where the chip tray or carrier tape containing multiple semiconductor chips is transported. Furthermore, when implementing the second measure, it is necessary to prepare a dedicated device (for example, a dicing apparatus) in advance at the destination (shipping destination) where the semiconductor wafer housed in the wafer cassette is transported.

Moreover, in the cases of implementing the first and the second measures, there is a possibility that the cost may increase due to the high expense of packaging materials such as aluminum bags.

Therefore, in recent years, there has been an increasing need (customer demand) to transport (ship) the diced semiconductor wafers, which are adhered and fixed to the dicing tape, to customers, etc., after performing the dicing step. This allows the semiconductor chips to be picked up from the diced semiconductor wafers adhered to the dicing tape at the destination (shipping destination) of the diced semiconductor wafers, and to be quickly utilized in the die bonding step.

However, it is difficult to vacuum-pack the dicing tape to which the diced semiconductor wafer is adhered in an aluminum bag. And, as mentioned above, silver (Ag) film is more prone to oxidation compared to gold (Au) film. Therefore, when transporting the dicing tape to which the diced semiconductor wafer is adhered, a new measure is required to prevent the oxidation of the silver film contained in the backside metal film of the semiconductor wafer.

### <About Main Features and Effects>

In the present embodiment, at Step S4, the backside SB2 of the semiconductor substrate (semiconductor wafer) SB is ground so that the thickness of the central portion CT of the semiconductor substrate SB becomes smaller than the thickness of the peripheral portion PR surrounding the central portion CT. Then, at step S5, a metal film ME containing a silver film ME3 is formed on the backside SB2 of the semiconductor substrate SB, and then, at step S6, a dicing tape DT is attached to the metal film ME on the backside SB2 of the semiconductor substrate SB. After that, at step S7, the semiconductor substrate SB (wafer WF1) is cut to separate the peripheral portion PR (PR1) from the central portion CT (CT1) and the dicing tape DT. Then, at step S8, the semiconductor substrate SB (wafer WF1) attached to the dicing tape DT is diced. After that, the semiconductor substrate SB (wafer WF1) that is attached to and diced on the dicing tape DT is transported to customers, etc., at step S10. That is, the structure KB is transported to customers, etc., at step S10.

To prevent the oxidation of the silver film ME3 contained in the metal film ME during the storage step at step S9, the transporting step at step S10, and the storage step at step S11 after the dicing step at step S8, it is effective to increase the adhesion between the dicing tape DT and the metal film ME. If the adhesion between the dicing tape DT and the metal film ME is high, it is difficult for air to exist between the metal film ME and the dicing tape DT, making the metal film ME less exposed to air, thus preventing the oxidation of the metal film ME, and consequently, preventing the oxidation of the silver film ME3 contained in the metal film ME.

In the present embodiment, at step S4, the back surface SB2 of the semiconductor substrate SB is ground so that the thickness of the central portion CT of the semiconductor substrate SB becomes smaller than the thickness of the peripheral portion PR of the semiconductor substrate SB. This improves the handling of the wafer WF after the back grinding step of step S4, can suppress or prevent warping of the wafer WF, and can reduce the thickness of the semiconductor chips CP obtained after the dicing step.

However, when the back surface SB2 of the semiconductor substrate SB is ground so that the thickness of the central portion CT of the semiconductor substrate SB becomes smaller than the thickness of the peripheral portion PR, without some ingenuity, it is difficult to increase the adhesion between the metal film ME on the back surface of the central portion CT of the semiconductor substrate SB and the dicing tape DT in the dicing tape attaching step. This is because a step is formed at the boundary between the central portion CT and the peripheral portion PR on the back surface of the semiconductor substrate SB, making it easy for a gap to occur between the metal film ME on the back surface of the central portion CT of the semiconductor substrate SB and the dicing tape DT. If the adhesion between the dicing tape DT and the metal film ME is low and a gap exists between the dicing tape DT and the metal film ME, air will be present between the metal film ME and the dicing tape DT, making the metal film ME prone to oxidation.

Therefore, in the present embodiment, a dicing tape DT having a base material layer BS made of polyvinyl chloride is used. Soft polyvinyl chloride is preferred as the polyvinyl chloride used for the base material layer BS. This allows the dicing tape DT to be closely adhered to the entire back surface of the wafer WF1 during the dicing tape adhering step S6, and enhances the adhesion between the metal film ME on the back surface of the central portion CT of the semiconductor substrate SB and the dicing tape DT. This will be explained more specifically.

The dicing tape adhering step S6, as described above, includes the steps of placing the wafer WF1 inside a vacuum container VC, reducing the pressure inside the vacuum container VC, placing the dicing tape DT on top of the wafer WF1, and opening the vacuum container VC to the atmosphere. The dicing tape DT placed on top of the wafer WF1 remains separated from the metal film ME on the central portion CT of the semiconductor substrate SB until the vacuum container VC is opened to the atmosphere. Subsequently, by opening the inside of the vacuum container VC to the atmosphere, the difference between the pressure that is between the dicing tape DT and the wafer WF1 and the pressure that is surrounding the wafer WF1 presses the dicing tape DT towards the wafer WF1. As a result, the dicing tape DT deforms to conform to the back surface of the wafer WF1, and the dicing tape DT is adhered to the entire back surface of the wafer WF1. Thus, the dicing tape DT comes into contact and adheres to the metal film ME on the back surface of the central portion of the semiconductor substrate SB.

Unlike the present embodiment, when a polyolefin film is used as the base material layer BS of the dicing tape DT, upon opening the vacuum container VC to the atmosphere, the dicing tape DT, even though attempting to deform to conform to the back surface of the wafer WF1, cannot deform exactly according to the shape of the back surface of the wafer WF1, and a gap is likely to form between the dicing tape DT and the back surface of the wafer WF1. This is because, for example, the elasticity of the polyolefin film is lower compared to that of the polyvinyl chloride film. Therefore, when a polyolefin film is used as the base material layer BS of the dicing tape DT, not only is a gap likely to form between the dicing tape DT and the wafer WF1, but this gap is also likely to widen.

In contrast, in the present embodiment, since a polyvinyl chloride film is used as the base material layer BS of the dicing tape DT, the base material layer BS is more likely to deform compared to when a polyolefin film is used. Viewed differently, the polyvinyl chloride film has higher elasticity compared to the polyolefin film. Therefore, in the present embodiment, when the vacuum container VC is opened to the atmosphere, the dicing tape DT is likely to deform according to the shape of the back surface of the wafer WF1. For this reason, the dicing tape DT, compared to when a polyolefin film is used, contacts and adheres to the entire back surface of the wafer WF1, thus suppressing the occurrence of gaps between the dicing tape DT and the back surface of the wafer WF1. Furthermore, even if a slight gap occurs between the dicing tape DT and the wafer WF1, the high elasticity of the polyvinyl chloride film can suppress the widening of the gap compared to when a polyolefin film is used. Therefore, the dicing tape DT can adhere to the entire back surface of the wafer WF1, and the adhesion between the metal film ME on the back surface of the central portion CT of the semiconductor substrate SB and the dicing tape DT can be enhanced. As a result, since air is less likely to be present between the metal film ME and the dicing tape DT, it is possible to prevent the silver film ME3 contained in the metal film ME from being oxidized during the storage step after the dicing step S8, the transport process step S10, and the storage step step S11. Also, it is possible to prevent the silver film ME3 contained in the metal film ME from being sulfidized during the storage step of Step S9, the transporting step of step S10 and the storage step of step S11 after the dicing step of Step S8.

The silver film discolors when oxidized or sulfidized. The inventors have confirmed that even after leaving the structure KB in the atmosphere for a long time (for example, about months) and then retrieving the semiconductor chip from that structure KB to observe the metal film ME, the silver film ME3 contained in the metal film ME does not discolor, and almost no oxidation or sulfidation of the silver film ME3 contained in the metal film ME occurs.

Therefore, even if the structure KB is left in the atmosphere for a long time during the storage step of Step S9, the transporting step of Step S10 and the storage step of Step S11 after the dicing step of Step S8, it is possible to prevent the silver film ME3 contained in the metal film ME from being oxidized and the silver film ME3 contained in the metal film ME from being sulfidized. This allows for the improvement of the performance and reliability of semiconductor devices manufactured using the semiconductor chip CP.

Furthermore, in the assembly process step S12, once the semiconductor chip CP is retrieved from the structure KB as shown in FIG. 28, the retrieved semiconductor chip CP can be quickly used (for example, within 5 minutes) for the die bonding step (placing the semiconductor chip CP on the die pad DP). This prevents the silver film ME3 contained in the metal film ME of the semiconductor chip CP picked up from the structure KB from oxidizing before the die bonding step.

Furthermore, in the present embodiment, it is possible to prevent the oxidation and sulfidation of the silver film ME3 included in the metal film ME in the structure KB, thereby allowing the time required for each of the storage step S9, the transport step S10, and the storage step S11 to be set as needed without concern for the oxidation of the silver film ME3 included in the metal film ME. Therefore, after dicing step S8, it is possible to perform the transport step S10 and the assembly step S12 at the desired timing.

Moreover, it is preferable that the surface of the metal film ME, that is, the surface of the silver film ME3, is roughened. This roughening treatment is performed after forming the metal film ME in step S5 and before the dicing tape attaching step S6. By roughening the surface of the metal film, ME, it is possible to further enhance the adhesion between the metal film ME and the dicing tape DT in the dicing tape attaching step S6. This makes it easier to prevent the oxidation and sulfidation of the silver film included in the metal film ME in the storage step S9, the transport step S10, and the storage step S11 after the dicing step S8.

As described above, by grinding the back surface SB2 of the semiconductor substrate SB in step S4, a step (step surface DS1) is formed at the boundary between the central portion CT and the peripheral portion PR on the back surface SB2 of the semiconductor substrate SB.

In Step S4, multiple steps may be formed at the boundary between the central portion CT and the peripheral portion PR on the back surface SB2 of the semiconductor substrate SB. In the case of the above FIG. 7, two steps (step surface DS1 and step portion DS2) are formed at the boundary between the central portion CT and the peripheral portion PR on the back surface SB2 of the semiconductor substrate SB.

Compared to when there is one step formed at the boundary between the central portion CT and the peripheral portion PR, when there are multiple steps formed at the boundary, gaps are more likely to occur between the back surface of the wafer WF1 and the dicing tape DT in the dicing tape attaching step S6. In contrast, in the present embodiment, since the dicing tape DT is made of polyvinyl chloride, not only when there is one step formed at the boundary between the central portion CT and the peripheral portion PR but also when there are multiple steps formed at the boundary, it is possible to adhere the dicing tape DT to the entire back surface of the wafer WF1, preventing gaps from occurring between the back surface of the wafer WF1 and the dicing tape DT. This allows for the prevention of oxidation and sulfidation of the silver film included in the metal film ME in the storage step S9, the transport step S10, and the storage step S11 after the dicing step.

Similarly to silver (Ag), copper (Cu) is less expensive than gold (Au) but is more prone to oxidation compared to gold (Au). Therefore, even when the metal film ME includes a copper (Cu) film instead of a silver film ME3, the same issues and effects as those described in the present embodiment can occur.

Therefore, the present embodiment can be applied even when the metal film ME includes a copper (Cu) film instead of the silver film ME3. That is, in the present embodiment, the metal film ME may have a copper (Cu) film instead of the silver film ME3.

The invention made by the present inventor has been described above in detail based on the embodiment, but the present invention is not limited to the embodiment described above, and it is needless to say that various modifications can be made without departing from the gist thereof.

What is claimed is:

1. A method of manufacturing a semiconductor device, comprising:
(a) preparing a semiconductor wafer having a first main surface and a second main surface opposite the first main surface;
(b) grinding the second main surface of the semiconductor wafer such that a thickness of a central portion of the semiconductor wafer is less than a thickness of a peripheral portion, surrounding the central portion, of the semiconductor wafer;
(c) after the (b), forming a metal film including a first metal film made of silver or copper on the second main surface of the semiconductor wafer;
(d) adhering a dicing tape to the second main surface of the semiconductor wafer via the metal film;
(e) after the (d), cutting the semiconductor wafer, and separating the peripheral portion from the central portion and the dicing tape;
(f) after the (e), dicing the semiconductor wafer adhered to the dicing tape; and
(g) after the (f), transporting the semiconductor wafer adhered to the dicing tape and diced, wherein the (d) includes:
(d1) placing the semiconductor wafer in a vacuum container;
(d2) after the (d1), depressurizing an inside of the vacuum container;
(d3) after the (d2), placing the dicing tape on the second main surface of the semiconductor wafer so as to be separated from the metal film; and
(d4) after the (d3), opening the inside of the vacuum container to the atmosphere,
wherein the dicing tape has a base material layer and an adhesive layer on the base material layer, and
wherein the base material layer is made of polyvinyl chloride.

2. The method according to claim 1,
wherein after the (d3), the dicing tape is separated from the metal film on the central portion of the semiconductor wafer, and
wherein by opening the inside of the vacuum container to the atmosphere in the (d4), the dicing tape comes into contact with the metal film on the central portion of the semiconductor wafer.

3. The method according to claim 2, wherein in the (d), the dicing tape is adhered to the metal film on the second main surface of the semiconductor wafer such that the adhesive layer of the dicing tape faces the metal film on the second main surface of the semiconductor wafer.

4. The method according to claim 3, wherein the adhesive layer is made of acrylic resin.

5. The method according to claim 1, wherein the first metal film is an uppermost layer of the metal film.

6. The method according to claim 1, further comprising:
(a1) after the (a) and before the (b), forming a semiconductor element on the first main surface of the semiconductor wafer or in the semiconductor wafer; and
(a2) after the (a1) and before the (b), forming a wiring structure on the first main surface of the semiconductor wafer.

7. The method according to claim 1, wherein a roughening treatment is performed to a front surface of the metal film.

8. The method according to claim 1, wherein a thickness of the base material layer is 70 micrometers or more, and 100 micrometers or less.

9. The method according to claim 1, wherein the metal film does not include a gold film.

10. The method according to claim 1, further comprising:
(g1) after the (g), obtaining a semiconductor chip from the semiconductor wafer adhered to the dicing tape and diced, and performing a die bonding step by using the semiconductor chip obtained.

11. The method according to claim 1, wherein in the (b), by grinding the second main surface of the semiconductor wafer, a step portion is formed at a boundary between the central portion and the peripheral portion.

12. The method according to claim 1, wherein in the (b), by grinding the second main surface of the semiconductor wafer, a plurality of step portions is formed at a boundary between the central portion and the peripheral portion.
